(19) United States
(12) Patent Application Publication
(10) Pub. No.: US 2024/0114654 A1
(43) Pub. Date: Apr. 4, 2024

(54) COOLING SYSTEM FOR A CIRCUIT BOARD THAT HOUSES A PLURALITY OF ELECTRONIC COMPONENTS THEREIN

(71) Applicant: Girish Mandakolathur Krishnamurthi, Bengaluru (IN)

(72) Inventor: Girish Mandakolathur Krishnamurthi, Bengaluru (IN)

(21) Appl. No.: 17/958,523

(22) Filed: Oct. 3, 2022

(51) Int. Cl. H05K 7/20; H05K 7/14

(52) U.S. Cl. CPC H05K 7/20272; H05K 7/1427; H05K 7/20154

(57) ABSTRACT

A cooling system for a circuit board that houses at least one electronic component therein is disclosed. The cooling system comprises at least one cooling channel provided to the circuit board and receives refrigerant therein for cooling the circuit board. A compressor is in flow communication with an outlet of the at least one cooling channel and compresses refrigerant flowing from the outlet of the at least one cooling channel. A condenser is in flow communication with an outlet of the compressor and discharges heat from refrigerant that is received from the compressor. An expansion device is in flow communication with an outlet of the condenser at its inlet and in flow communication with an inlet of the at least one cooling channel at its outlet. The expansion device controls a flow of refrigerant from the condenser to the inlet of the at least one cooling channel is also disclosed.

### FIELD OF THE INVENTION

This invention relates generally to a cooling system for a circuit board, and more particularly to the cooling system for cooling a printed circuit board that houses a plurality of electronic components therein.

### BACKGROUND OF THE INVENTION

In a current design of a circuit board such as but not limited to a printed circuit board that is commonly referred to as a PCB, a stream of high speed cooling air from a cooling fan is allowed to impinge on an outer surface of the printed circuit board. The stream of high speed cooling air from the cooling fan that impinges on the outer surface of the printed circuit board absorbs heat from a plurality of high temperature electronic components that are positioned in the printed circuit board. The absorption of heat from the plurality of high temperature electronic components that are positioned in the printed circuit board by the stream of high speed cooling air cools the high temperature electronic components to a lower operating temperature. The reduction in the temperature of the plurality of high temperature electronic components that are positioned in the printed circuit board facilitate decreasing an electrical resistance of the plurality of high temperature electronic components. The decrease in the electrical resistance of the plurality of high temperature electronic components that are positioned in the printed circuit board increases an operating efficiency of the plurality of high temperature electronic components. In addition, due to the decrease in the temperature of the plurality of high temperature electronic components, a longevity and hence a useful life of the plurality of electronic components that are positioned in the printed circuit board may be substantially enhanced. A cooling fan that directs a stream of high speed cooling air on the outer surface of the printed circuit board is designed to operate at a constant speed, thereby directing cooling air at a same rate on the outer surface of the printed circuit board. Due to the cooling fan that directs the same stream of high speed cooling air on the outer surface of the printed circuit board to cool the printed circuit board regardless of an actual temperature of the printed circuit board and an actual temperature of the plurality of electronic components that are positioned in the printed circuit board, absorption of heat from the plurality of electronic components that are positioned in the printed circuit board occurs at a non-uniform rate. Once the heat from the plurality of electronic components that are positioned in the printed circuit board is absorbed by the high speed cooling air that impinges on the outer surface of the printed circuit board, the high speed cooling air is discharged to an external environment.

However, as the high speed cooling air that impinges on the plurality of electronic components that are positioned in the printed circuit board is of a low specific heat absorption capacity, absorption of heat from the plurality of electronic components that are positioned in the printed circuit board per unit mass of high speed cooling air that is discharged from the cooling fan is low. Therefore, energy expended by the cooling fan to discharge high speed cooling air to cool the plurality of electronic components that are positioned in the printed circuit board until the plurality of electronic components that are positioned in the printed circuit board is cooled by a required temperature differential is correspondingly high. A solution is hereby proposed in this manuscript to circulate a refrigerant through a plurality of cooling channels provided in the cooling circuit board that is secured against the printed circuit board via fastening means to absorb heat from the plurality of high temperature electronic components that are positioned in the printed circuit board. The absorption of heat from the plurality of high temperature electronic components that are positioned in the printed circuit board by the refrigerant that is circulated through the plurality of cooling channels provided in the cooling circuit board results in an increase in a mechanical efficiency of the cooling system for the printed circuit board that houses the plurality of electronic components therein. Moreover, as the refrigerant is in a gaseous state after absorbing heat from the plurality of high temperature electronic components that are positioned in the printed circuit board as well as the printed circuit board, energy required to circulate gaseous refrigerant through the cooling system for the printed circuit board that houses the plurality of electronic components therein is low. In addition, the specific heat absorption capacity per unit volume of the refrigerant is much higher than the specific heat absorption capacity per unit volume of the high speed cooling air that is discharged from the cooling fan and impinges on the plurality of electronic components that are positioned in the printed circuit board as well as the printed circuit board. Therefore, an efficiency of heat absorption by the refrigerant that is channeled through the cooling system for the printed circuit board that houses the plurality of electronic components therein is higher than an efficiency of heat absorption by high speed cooling air that is discharged from the cooling fan and impinges on the printed circuit board.

A traditional cooling system for the printed circuit board that houses the plurality of electronic components therein includes a cooling fan that is positioned at an angle with respect to the printed circuit board and discharges a flow of high speed cooling air on the surface of the printed circuit board that houses the plurality of electronic components therein. The cooling air that is discharged from the cooling fan and impinges on the surface of the printed circuit board that houses the plurality of electronic components therein absorbs heat from the plurality of electronic components that are positioned in the printed circuit board as well as the printed circuit board itself, thereby cooling the plurality of electronic components and the printed circuit board respectively. After absorbing heat from the plurality of electronic components and the printed circuit board, the high speed cooling air is discharged to the external environment. Consequently, a temperature of the plurality of electronic components that are each positioned in the printed circuit board is decreased by constant temperature differentials for various operating temperatures of the plurality of electronic components and the printed circuit board. However, a mass flow rate of high speed cooling air that is required to be discharged from the cooling fan and allowed to impinge on the plurality of electronic components and the printed circuit board in order to achieve the constant temperature reduction in the plurality of electronic components and the printed circuit board is high due to the low specific heat absorption capacity of high speed cooling air. Moreover, due to the high mass flow rate of high speed cooling air that is required to be discharged from the cooling fan and allowed to impinge on the plurality of electronic components and the printed circuit board, energy expended by the cooling fan to discharge the high speed cooling air that impinges on the surface of the printed circuit board that houses the plurality of electronic components therein to achieve the required temperature reduction in the plurality of electronic components and the printed circuit board is high. Owing to the high mass flow rate of the high speed cooling air, a mechanical efficiency of the current cooling system for cooling the printed circuit board and the plurality of electronic components that are positioned in the printed circuit board is low. Consequently, there exists a need for an improved cooling system for the printed circuit board that would enable a lower mass flow rate of refrigerant than that of high speed cooling air to be channeled through a plurality of cooling channels provided in the printed circuit board in order to achieve the required temperature reduction in the plurality of electronic components that are positioned in the printed circuit board as well as the printed circuit board due to the high specific heat absorption capacity of the refrigerant. Due to the change in the phase of the refrigerant from the liquid phase to the gaseous phase as refrigerant flows through the plurality of cooling channels of the printed circuit board and owing to the lower mass flow rate of refrigerant that is required to be channeled through the plurality of cooling channels of the printed circuit board, energy expended by a compressor to circulate gaseous refrigerant through the plurality of cooling channels of the printed circuit board to achieve the required temperature reduction in the plurality of electronic components of the printed circuit board as well as the printed circuit board is low.

The need has existed for many years, yet there is no fully satisfactory system to meet the need. In accord with a long recognized need, there has been developed a cooling system for an electronic circuit board that houses the plurality of electronic components therein that would enable refrigerant to be channeled through the plurality of cooling channels provided to the electronic circuit board. In an alternate exemplary embodiment, the electronic circuit board may be but is not limited to the printed circuit board. The refrigerant that is channeled through the plurality of cooling channels of the printed circuit board changes its phase from the liquid phase to the gaseous phase as refrigerant flows from an inlet port that is in flow communication with the plurality of cooling channels to an outlet port that is in flow communication with the plurality of cooling channels of the printed circuit board. The refrigerant that is channeled through the plurality of cooling channels of the printed circuit board is designed to increase the mechanical efficiency of the cooling system for the printed circuit board as well as an efficiency of operation of the printed circuit board. More specifically, as the specific heat absorption capacity of the refrigerant is high in comparison with the specific heat absorption capacity of high speed cooling air that is low, the mass flow rate of the refrigerant that is required to be channeled through the plurality of cooling channels provided to the printed circuit board that houses the plurality of electronic components therein can be substantially decreased in comparison with a high mass flow rate of high speed cooling air that is required to be discharged from the cooling fan and allowed to impinge on the plurality of electronic components that are positioned in the printed circuit board and the printed circuit board itself in order to achieve a substantially same temperature reduction thereof. Moreover, as the refrigerant changes from the liquid state to the gaseous state as refrigerant flows through the plurality of cooling channels provided to the printed circuit board, energy required to circulate the gaseous refrigerant through the cooling system of the printed circuit board by means of a compressor may be substantially decreased in contrast with energy required to discharge high speed cooling air from the cooling fan that impinges on the plurality of electronic components that are positioned in the printed circuit board.

### BRIEF DESCRIPTION OF THE INVENTION

In one aspect of the invention, a method of production of a circuit board is described. The method comprises providing at least one cooling channel to the circuit board that houses at least one electronic component therein, wherein the at least one cooling channel comprises an inlet port and an outlet port. The method further comprises channeling refrigerant in a substantially liquid state at a low temperature through the inlet port of the at least one cooling channel such that the refrigerant that is channeled in the substantially liquid state at the low temperature through the inlet port of the at least one cooling channel flows through the at least one cooling channel to cool the circuit board that houses at least one electronic component therein, and delivering refrigerant that flows through the at least one cooling channel to cool the circuit board that houses at least one electronic component therein through the outlet port of the at least one cooling channel in a substantially gaseous state at a high temperature due to absorption of heat by the refrigerant from the circuit board that houses at least one electronic component therein.

In another aspect of the invention, a cooling system for a circuit board that houses at least one electronic component therein is described. The cooling system comprises at least one cooling channel provided to the circuit board and receives a refrigerant therein. The refrigerant that is received in the at least one cooling channel flows through the at least one cooling channel provided to the circuit board to cool the circuit board that houses at least one electronic component therein. A compressor is in flow communication with an outlet port of the at least one cooling channel provided to the circuit board. The compressor receives refrigerant that flows through the outlet port of the at least one cooling channel. The compressor compresses the refrigerant that is received in the compressor. A condenser is in flow communication with an outlet port of the compressor. The condenser receives refrigerant that flows through the outlet port of the compressor and discharges heat from the refrigerant that is received in the condenser. An expansion device is in flow communication with an outlet port of the condenser at its inlet port and receives refrigerant that flows through the outlet port of the condenser. The expansion device is in flow communication with an inlet port of the at least one cooling channel provided to the circuit board at its outlet port. The expansion device controls a flow of refrigerant that flows through the outlet port of the condenser to the inlet port of the at least one cooling channel provided to the circuit board.

In a further aspect of the invention, a circuit board is described. The circuit board comprises at least one cooling channel provided to the circuit board. The at least one cooling channel comprises an inlet port and an outlet port. The inlet port of the at least one cooling channel receives low temperature refrigerant in a substantially liquid state, wherein the low temperature refrigerant in the substantially liquid state that is received through the inlet port of the at least one cooling channel flows through the at least one cooling channel to cool the circuit board by absorbing heat from the circuit board. High temperature refrigerant in a substantially gaseous state is delivered through the outlet port of the at least one cooling channel.

### BRIEF DESCRIPTION OF THE DRAWINGS

FIG. 1 is a schematic representation of a cooling system for a circuit board that houses a plurality of electronic components therein in one embodiment of the invention.

FIG. 2 is a schematic representation of a cooling circuit board for cooling a plurality of electronic components of a circuit board that is in flow communication with a compressor, a condenser, and an expansion device in one embodiment of the invention.

FIG. 3 is a flowchart representing a method of production of a circuit board in one embodiment of the invention.

### DETAILED DESCRIPTION OF THE INVENTION

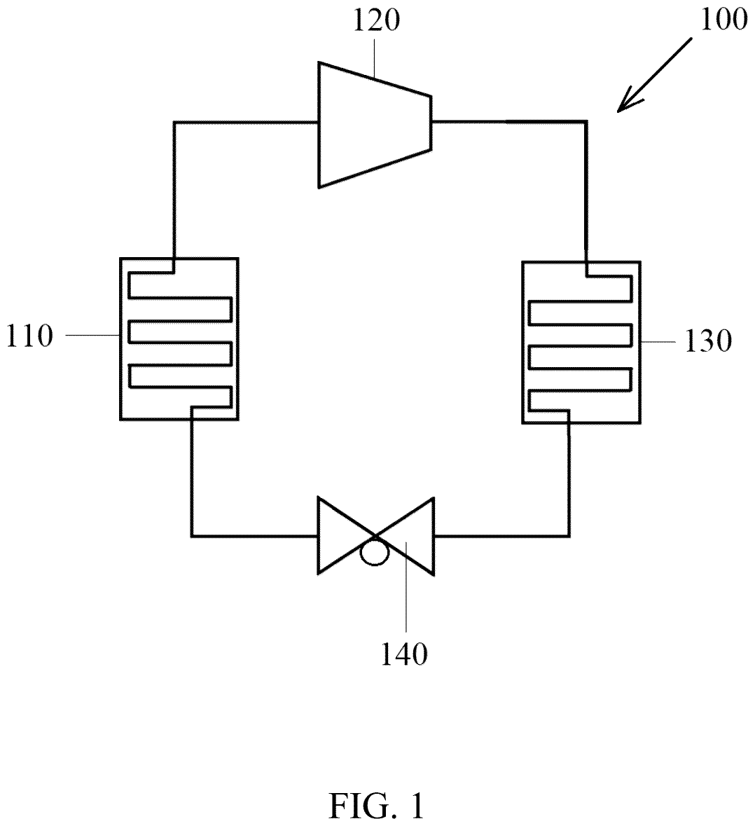

FIG. 1 is a schematic representation of a cooling system 100 for a circuit board 110 that houses a plurality of electronic components therein in one embodiment of the invention. The cooling system 100 for the circuit board 110 that houses the plurality of electronic components therein comprises at least one cooling channel that is provided to the circuit board 110 that receives a refrigerant from an expansion device 140 via an inlet port defined in the at least one cooling channel, wherein the refrigerant that is received in the at least one cooling channel flows through the at least one cooling channel provided to the circuit board 110 and past the circuit board 110 that houses the plurality of electronic components therein for cooling the circuit board 110, and wherein the refrigerant from the at least one cooling channel provided to the circuit board 110 flows to a compressor 120 via an outlet port that is defined in the at least one cooling channel.

More specifically, the at least one cooling channel that is provided to the circuit board 110 receives refrigerant that is in a substantially liquid state via the inlet port that is defined in the at least one cooling channel. When the liquid refrigerant flows past the circuit board 110 that houses the plurality of electronic components therein for cooling the plurality of electronic components, heat is absorbed from the plurality of electronic components by the liquid refrigerant, thereby changing its state to a substantially gaseous state. The refrigerant that is in the substantially gaseous state is channeled from the at least one cooling channel to the compressor 120 via the outlet port that is defined in the at least one cooling channel. In an exemplary embodiment, the circuit board 110 that houses the plurality of electronic components therein may be a printed circuit board that houses the plurality of electronic components therein. In an alternate exemplary embodiment, the circuit board 110 that houses the plurality of electronic components therein may be any kind of an electronic circuit board known in the art that houses the plurality of electronic components therein. More specifically, the circuit board 110 that houses the plurality of electronic components therein may be any electronic circuit board known in the art that requires to be cooled as a consequence of heating up due to the heating up of the plurality of electronic components that are positioned in the circuit board 110 due to current flowing through the plurality of electronic components that are positioned in the circuit board 110.

Once the refrigerant absorbs heat from the circuit board 110 that houses the plurality of electronic components therein, the refrigerant from the circuit board 110 is channeled to the compressor 120 for compressing the refrigerant that flows from the circuit board 110. Once refrigerant is compressed in the compressor 120, the compressed refrigerant is channeled to a condenser 130 for discharging heat from the compressed refrigerant. Therein, the refrigerant is channeled to the expansion device 140 for throttling the refrigerant and thereby regulating a flow of the refrigerant to the circuit board 110. The refrigerant from the expansion device 140 is channeled back to the circuit board 110 that houses the plurality of electronic components therein and recirculated through the cooling system 100 for absorbing heat from the circuit board 110 that houses the plurality of electronic components therein.

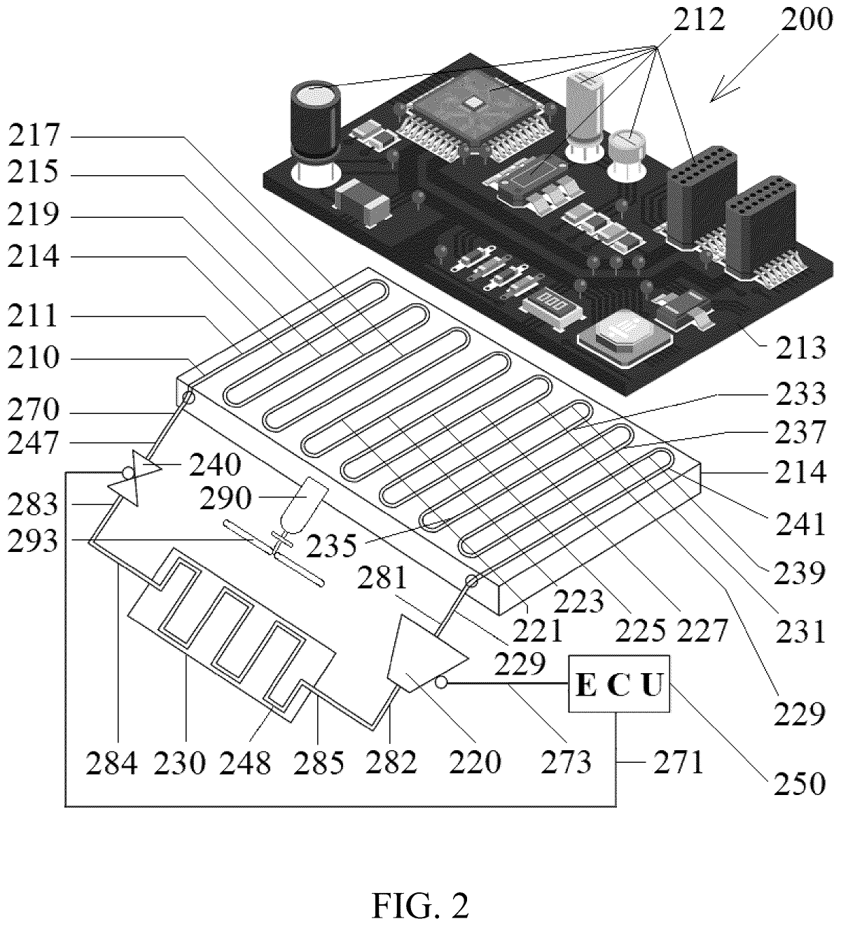

FIG. 2 is a schematic representation of a cooling system 200 comprising a cooling circuit board 214 comprising a plurality of cooling channels that are in flow communication with a compressor 220, a condenser 230, and an expansion device 240 in one embodiment of the invention. The cooling circuit board 214 may be secured to the circuit board 213 that houses the plurality of electronic components 212 therein and cools the circuit board 213 from a higher temperature to a lower temperature. In an exemplary embodiment, the cooling circuit board 214 comprises at least one cooling channel 210 that is provided in the cooling circuit board 214 and receives a refrigerant therein. In an exemplary embodiment, the refrigerant deployed in the cooling circuit board 214 may be one of Formaldehyde, R-11, R-12, R-22, R-32, R-115, R-134A, R-290, R-407C, R-410A, and R-600A. In an alternate exemplary embodiment, the refrigerant that is deployed in the cooling system 200 for the circuit board 213 that houses the plurality of electronic components 212 therein may be any refrigerant known in the art that cools the circuit board 213 which becomes heated up due to the transfer of heat from the plurality of electronic components 212 that are positioned in the circuit board 213 to the circuit board 213 by the process of conduction.

More specifically, the at least one cooling channel 210 that is provided in the cooling circuit board 214 comprises a plurality of cooling channels that are provided within the cooling circuit board 214. The plurality of cooling channels that are provided within the cooling circuit board 214 comprises a first cooling channel 211, a second cooling channel 214, a third cooling channel 219, a fourth cooling channel 215, a fifth cooling channel 217, a sixth cooling channel 221, a seventh cooling channel 223, an eighth cooling channel 225, a ninth cooling channel 227, a tenth cooling channel 229, a eleventh cooling channel 231, a twelfth cooling channel 233, a thirteenth cooling channel 235, a fourteenth cooling channel 237, a fifteenth cooling channel 239, and a sixteenth cooling channel 241 respectively that extends through the cooling circuit board 214 are in flow communication with one another and are located within the cooling circuit board 214 between an upper surface of the cooling circuit board 214 and a lower surface of the cooling circuit board 214. In an alternate exemplary embodiment, at least one cooling channel 210 that is provided in the cooling circuit board 214 comprises the first cooling channel 211, the second cooling channel 214, the third cooling channel 219, the fourth cooling channel 215, the fifth cooling channel 217, the sixth cooling channel 221, the seventh cooling channel 223, the eighth cooling channel 225, the ninth cooling channel 227, the tenth cooling channel 229, the eleventh cooling channel 231, the twelfth cooling channel 233, the thirteenth cooling channel 235, the fourteenth cooling channel 237, the fifteenth cooling channel 239, and the sixteenth cooling channel 241 are in flow communication with one another and are located on one o the upper surface of the cooling circuit board 214 and the lower surface of the cooling circuit board 214. The plurality of cooling channels that are provided in the cooling circuit board 214 are arranged in a zig-zag arrangement that facilitates covering a maximum possible surface area of the cooling circuit board 214 to facilitate absorbing a maximum quantity of heat from the circuit board 213 that houses the plurality of electronic components 212 therein. In addition, the plurality of cooling channels that are provided in the cooling circuit board 214 may be arranged in any pattern and any length of spacing between each of the plurality of cooling channels to facilitates encompassing the maximum possible surface area of the cooling circuit board 214 to facilitate absorbing the maximum quantity of heat from the circuit board 213 that houses the plurality of electronic components 212 therein. Therefore, the plurality of cooling channels cover a maximum surface area of the cooling circuit board 214 to facilitate absorbing the maximum quantity of heat from the circuit board 214 that houses the plurality of electronic components 212 therein by means of the refrigerant, thereby cooling the circuit board 213 that houses the plurality of electronic components 212 therein as well as the plurality of electronic components 212 that are positioned in the circuit board 213 effectively. In an exemplary embodiment, the plurality of cooling channels may extend either along a longitudinal axis of the cooling circuit board 214 or perpendicular to the longitudinal axis of the cooling circuit board 214 to encompass a maximum surface area of the cooling circuit board 214. In a further exemplary embodiment, at least one cooling channel (not shown) branches out from the at least one cooling channel 210 and is directed to a specific portion of the cooling circuit board 214 where there exist hot spots in the circuit board 213 are in contact with the specific portion of the cooling circuit board 214 and that require to be cooled. In an exemplary embodiment, the at least one cooling channel that branches out from the at least one cooling channel 210 may be integrally formed in the circuit board 213 or the cooling circuit board 214 such that the at least one cooling channel that branches out from the at least one cooling channel 210 constitutes a unitary assembly with the circuit board 213 or the cooling circuit board 214 respectively.

In the exemplary embodiment, the refrigerant that is received within the at least one cooling channel 210 is received within the at least one cooling channel 210 in a substantially liquid state. Once the refrigerant is received within the at least one cooling channel 210 in the substantially liquid state, the refrigerant is allowed to flow through the at least one cooling channel 210 provided within the cooling circuit board 214 to facilitate cooling the circuit board 213 that houses the plurality of electronic components 212 therein. More specifically, the refrigerant is allowed to flow through each of the plurality of cooling channels that are in flow communication with one another to facilitate cooling the circuit board 213 that houses the plurality of electronic components 212 therein. Therefore, the refrigerant that flows through the plurality of cooling channels that are in flow communication with one another facilitate absorbing heat from the circuit board 213 that houses the plurality of electronic components 212 therein. The absorption of heat by the refrigerant from the circuit board 213 that houses the plurality of electronic components 212 therein cools the circuit board 213 as well as the plurality of electronic components 212 that are positioned in the circuit board 213 from higher operating temperatures to lower operating temperatures respectively.

In an exemplary embodiment, the compressor 120 is in flow communication with an outlet port 229 of the at least one cooling channel 210 provided within the cooling circuit board 214 and receives substantially gaseous refrigerant that flows from the outlet port 229 of the at least one cooling channel 210. More specifically, the refrigerant that is received within the compressor 120 from the at least one cooling channel 210 is in the substantially gaseous state and is received via an inlet port 281 of the compressor 120. Once the refrigerant is received within the compressor 120 in the substantially gaseous state, the gaseous refrigerant is compressed by the compressor 120 from a pressure that is equal to the pressure of the refrigerant at the outlet port 229 of the at least one cooling channel 210 to a higher pressure that is required for the refrigerant to be circulated through the cooling system 200 for the circuit board 213 that houses the plurality of electronic components 212 therein. More specifically, the compressor 120 may be an electric compressor that is driven by electric power supplied from an electric battery to increase the pressure of refrigerant from the low pressure at the outlet port 229 of the at least one cooling channel 210 to the higher pressure. In an exemplary embodiment, the compressor 120 may be any compressor 120 known in the art that increases the pressure of refrigerant from the low pressure at the outlet port 229 of the at least one cooling channel 210 to the higher pressure. Therefore, as the refrigerant is received in the compressor 120, the pressure of the refrigerant is increased by the compressor 120 from the low pressure to the high pressure with a corresponding large increase in temperature of the refrigerant that is in the substantially gaseous state. More specifically, owing to the large increase in the pressure of the gaseous refrigerant by the compressor 120, the temperature of the gaseous refrigerant is substantially increased to a high temperature. In an exemplary embodiment, a condenser 130 is in flow communication with an outlet port 282 of the compressor 120. In an exemplary embodiment, an outlet valve (not shown) is in flow communication between the outlet port 229 of the at least one cooling channel 210 and the inlet port 281 of the compressor 220. More specifically, the outlet valve is in flow communication between the outlet port 229 of the at least one cooling channel 210 and the inlet port 281 of the compressor 120 and is electronically connected to the electronic control unit 250 via a control flow path 273 and controls a flow of refrigerant from the outlet port 229 of the at least one cooling channel 210 to the inlet port 281 of the compressor 220.

In an exemplary embodiment, a condenser 130 is in flow communication with the outlet port 282 of the compressor 120 at its inlet port 285 and receives refrigerant that flows from the outlet port 282 of the compressor 120. More specifically, the refrigerant that is received within the condenser 130 via its inlet port 285 is received from the compressor 220 in a substantially gaseous state. Once the refrigerant is received within the condenser 130 in the substantially gaseous state, heat that is present within the gaseous refrigerant that was absorbed from the circuit board 213 that houses the plurality of electronic components 212 therein while the refrigerant was flowing through the at least one cooling channel 210 provided in the cooling circuit board 214 as well as from the compressor 120 is dissipated in the condenser 130. The heat from the gaseous refrigerant is discharged in the condenser 130, thereby decreasing the temperature of the gaseous refrigerant from the temperature of the refrigerant at the outlet port 282 of the compressor 120 to a lower temperature that is required for the refrigerant to be circulated through the cooling system 100 for the circuit board 110 that houses the plurality of electronic components 212 therein. More specifically, the condenser 130 may be a mechanical heat exchanger for discharging the heat from the gaseous refrigerant that flows into the condenser 130 to an external environment. More specifically, the heat exchanger may be one of a liquid cooled and an air cooled heat exchanger that facilitates decreasing the temperature of the refrigerant from the temperature at the outlet port 282 of the compressor 220 to a lower temperature that is required for the refrigerant to be circulated through the cooling system 100 for the circuit board 110 that houses the plurality of electronic components 212 therein. In an alternate exemplary embodiment, the condenser 130 may be any condenser 130 known in the art that facilitates decreasing the high temperature of the gaseous refrigerant that is received in the condenser 130 via its inlet port 285 to the lower temperature that is required for the gaseous refrigerant to be circulated through the cooling system 100 for the circuit board 110 that houses the plurality of electronic components 212 therein. As the temperature of the gaseous refrigerant decreases from the high temperature at the outlet port 282 of the compressor 120 to the lower temperature that is required for the refrigerant to be circulated through the cooling system 100 for the circuit board 110 that houses the plurality of electronic components 212 therein, the pressure of the refrigerant remains largely unaffected. More specifically, while the temperature of the gaseous refrigerant decreases as the refrigerant flows through the condenser 130, the pressure of the gaseous refrigerant remains steady or decreases to a slightly lower pressure from the high pressure gaseous refrigerant that is channeled from the outlet port 282 of the compressor 220 to the condenser 230 via the inlet port 285 of the condenser 130. Therefore, at an outlet port 284 of the condenser 130, gaseous refrigerant at high pressure and low temperature is channeled to the next stage of the cooling system 100 for the circuit board 110 that houses the plurality of electronic components 212 therein. In an exemplary embodiment, an expansion device 140 is in flow communication with the outlet port 284 of the condenser 130.

In an exemplary embodiment, the expansion device 140 is in flow communication with the outlet port 284 of the condenser 130 at its inlet port 283 and receives refrigerant that flows through the outlet port 284 of the condenser 230. More specifically, the refrigerant that is received at the inlet port 283 of the expansion device 140 is received from the outlet port 284 of the condenser 230 in a substantially gaseous state. Once the refrigerant is received at the inlet port 283 of the expansion device 140 in the substantially gaseous state, the expansion device 140 facilitates throttling the gaseous refrigerant, thereby decreasing the pressure of the gaseous refrigerant from the high pressure at the outlet port 284 of the condenser 130 to a lower pressure, and consequently decreasing the temperature of the gaseous refrigerant at the outlet port 284 of the condenser 130 to a lower temperature. More specifically, the decrease in the pressure of gaseous refrigerant from the high pressure at the outlet port 284 of the condenser 230 to the lower pressure due to the throttling action of the expansion device 140 causes a substantial reduction in the temperature of refrigerant from the temperature at the outlet port 284 of the condenser 130 to the lower temperature. An outlet port 247 of the expansion device 140 is in flow communication with an inlet port 270 of the at least one cooling channel 210 provided in the cooling circuit board 214. The expansion device 140 controls the flow of refrigerant that flows through the outlet port 284 of the condenser 130 to the inlet port 270 of the at least one cooling channel 210 provided in the cooling circuit board 214. More specifically, the electronic control unit 250 is in electronic communication with the expansion device 140 via a control flow path 271. The electronic control unit 250 controls an opening percentage of the expansion device 140 to facilitate regulating a required mass flow rate of the gaseous refrigerant from the outlet port 284 of the condenser 130 to the inlet port 270 of the at least one cooling channel 210 provided in the cooling circuit board 214 for the refrigerant to be circulated through the cooling system 100 for the circuit board 110 that houses the plurality of electronic components 212 therein. In addition, the electronic control unit 250 is in electronic communication with the compressor 220 via a control flow path 273. More specifically, the electronic control unit 250 controls a speed of the compressor 220 to facilitate regulating the required mass flow rate of the refrigerant that is to flow from the outlet port 229 of the at least one cooling channel 210 to the inlet port 285 of the condenser 230 for the refrigerant to be circulated through the cooling system 100 for the circuit board 110 that houses the plurality of electronic components 212 therein. More specifically, the expansion device 140 may be a mechanical control valve for controlling a flow of refrigerant from the outlet port 284 of the condenser 130 to the inlet port 270 of the at least one cooling channel 210 provided in the cooling circuit board 214. In an alternate exemplary embodiment, the expansion device 140 may be an electronically actuated control valve for controlling the flow of refrigerant from the outlet port 284 of the condenser 130 to the inlet port 270 of the at least one cooling channel 210 provided in the cooling circuit board 214. In an alternate exemplary embodiment, the expansion device 140 may be any expansion device known in the art that facilitates controlling the flow of refrigerant from the outlet port 284 of the condenser 130 to the inlet port 270 of the at least one cooling channel 210 provided in the cooling circuit board 214.

As the pressure and the temperature of the refrigerant decreases from the high pressure and the low temperature at the outlet port 284 of the condenser 130 to the low pressure and much lower temperature at the outlet port 247 of the expansion device 240, the gaseous refrigerant changes its phase to a substantially liquid phase due to a drastic reduction in the temperature of the refrigerant. The refrigerant that is in the substantially liquid phase is allowed to flow through the inlet port 270 of the at least one cooling channel 210 provided in the cooling circuit board 214 via the outlet port 247 of the expansion device 240 that throttles the refrigerant that flows from the outlet port 284 of the condenser 230. The throttling effect of the gaseous refrigerant that flows through the outlet port 284 of the condenser 230 to the inlet port 270 of the at least one cooling channel 210 via the outlet port 247 of the expansion device 240 is controlled by the electronic control unit 250 via the control flow path 271 and permits only a required mass flow rate of liquid refrigerant to be channeled at a high speed through the inlet port 270 of the at least one cooling channel 210. Therefore, at the outlet port 247 of the expansion device 240, substantially liquid refrigerant at a lower pressure and at a lower temperature than the pressure and the temperature of the refrigerant at the outlet port 284 of the condenser 130 is channeled to the next stage of the cooling system 100 for the circuit board 213 that houses the plurality of electronic components 212 therein. In an exemplary embodiment, the at least one cooling channel 210 provided in the cooling circuit board 214 is in flow communication with the outlet port 247 of the expansion device 240 and receives high speed substantially liquid refrigerant at a low pressure and at a low temperature therein. The expansion device 240 described above may be a unidirectional flow control expansion device that permits only a required mass flow rate of substantially liquid refrigerant to be channeled at the high speed, low pressure, and low temperature through the inlet port 270 of the at least one cooling channel 210 provided in the cooling circuit board 214.

In an exemplary embodiment, the circuit board 213 includes the at least one cooling channel 210 and the plurality of electronic components 212 is a unitary circuit board. More specifically, the circuit board 213 may include the at least one cooling channel 210 that is provided in the circuit board 213 and extends between the inlet port 270 of the at least one cooling channel 210 and an outlet port 229 of the at least one cooling channel 210 as well as the plurality of electronic components 212 that are positioned in the circuit board 213 in a single integrated circuit board 213 and not two discrete circuit boards that may be secured to one another. Therefore, in this arrangement, both the at least one cooling channel 210 and the plurality of electronic components 212 may be integrally provided in the same circuit board 213 itself without having to assemble the at least one cooling channel 210 and the plurality of electronic components 212 on independent circuit boards and coupling the independent circuit boards together to constitute an assembly. In an alternate exemplary embodiment, the cooling circuit board5 214 comprises at least one cooling channel 210 that is provided in the cooling circuit board 214 and extends between the inlet port 270 of the at least one cooling channel 210 and the outlet port 229 of the at least one cooling channel 210. The cooling circuit board 214 that comprises at least one cooling channel 210 that is provided to the cooling circuit board 214 is mechanically secured to the circuit board 213 by positioning an upper surface of the cooling circuit board 214 against a lower surface of the circuit board 213 that houses the plurality of electronic component 212 on the upper surface of the circuit board 213. Therein, the upper surface of the cooling circuit board 214 that comprises at least one cooling channel 210 is secured to the lower surface of the circuit board 213 that houses the plurality of electronic components 212 on the upper surface of the circuit board 213 by means of a fastener that may be provided at the mating interfaces of the cooling circuit board 214 and the circuit board 213 respectively. In an exemplary embodiment, the fastener that secures the upper surface of the cooling circuit board 214 that comprises at least one cooling channel 210 to the lower surface of the circuit board 213 that houses the plurality of electronic components 212 on the upper surface of the circuit board 212 may be a welded joint, a liquid adhesive, a semi-solid adhesive, silica-gel, or a mechanical fastener such as but not limited to a screw and nut assembly, and a mechanical rivet. In an alternate exemplary embodiment, the fastener that secures the upper surface of the cooling circuit board 214 that comprises at least one cooling channel 210 to the lower surface of the circuit board 213 that houses the plurality of electronic components 212 on the upper surface of the circuit board 213 may be any kind of fastening means known in the art that facilitates securing the upper surface of the cooling circuit board 214 to the lower surface of the circuit board 213. In yet another alternate exemplary embodiment, the fastener may only be applied on the mating side interfaces of the cooling circuit board 214 that comprises at least one cooling channel 210 and the circuit board 213 that houses the plurality of electronic components 212 therein to facilitate securing the cooling circuit board 214 to the circuit board 213. The cooling circuit board 214 may be manufactured from a flat laminated composite made from non-conductive substrate materials, FR-1, G-10, PTFE, alumina, Kapton, and lightweight polyester. In an alternate exemplary embodiment, the cooling circuit board 214 may be manufactured from any substate material that facilitates integrating the plurality of cooling channels within a substrate of the cooling circuit board 214.

In an exemplary embodiment, the at least one cooling channel 210 provided in the cooling circuit board 214 may be at least one micro-channel that receives a refrigerant therein. Therein, a diameter of the micro-channel that receives the refrigerant therein may be in the range of 0.01 millimeters to 0.2 millimeters to facilitate the flow of refrigerant through the at least one micro-channel. Alternatively, the diameter of the micro-channel that receives the refrigerant therein may be of the order of any diametrical range known in the art that facilitates the flow of refrigerant from the inlet port 270 of the micro-channel to the outlet port 229 of the micro-channel. In yet another alternate exemplary embodiment, the at least one cooling channel 210 provided in the cooling circuit board 214 may be at least one mini-channel that receives a refrigerant therein. Therein, a diameter of the mini-channel that receives the refrigerant therein may be in the range of 0.2 millimeters to 3 millimeters to facilitate the flow of refrigerant through the at least one mini-channel. Alternatively, the diameter of the mini-channel that receives the refrigerant therein may be of the order of any diametrical range known in the art that facilitates the flow of refrigerant from the inlet port 270 of the mini-channel to the outlet port 229 of the mini-channel.

In an exemplary embodiment, the plurality of electronic components 212 are positioned in the circuit board 213 and generates heat due to current that flows through the plurality of electronic components that are positioned in the circuit board 213. The heat that is generated by the plurality of electronic components that are positioned in the circuit board 213 is discharged to the circuit board 213 itself by conduction and consequently heats up the circuit board 213 that houses the plurality of electronic components 212 therein. Therefore, the refrigerant that flows through the at least one cooling channel 210 provided in the cooling circuit board 214 cools the plurality of electronic components 212 that is positioned in the circuit board 213. More specifically, as the refrigerant flows through the plurality of cooling channels 210 provided in the circuit board 213, the heat that is dissipated from the plurality of electronic component that is positioned in the circuit board 213 to the circuit board 213 is absorbed by the refrigerant by convection as refrigerant flows from the inlet port 270 of the at least one cooling channel 210 to the outlet port 229 of the at least one cooling channel 210. The absorption of heat by the refrigerant from the circuit board 213 facilitates cooling the heated circuit board 213 and consequently the heated plurality of electronic components 212 that is positioned in the heated circuit board 213. Therefore, once the refrigerant flows through the at least one cooling channel 210 that is provided in the cooling circuit board 214, the refrigerant cools the plurality of electronic components 212 that is positioned in the circuit board 213. More specifically, as the substantially liquid refrigerant that is at a high speed, low pressure, and low temperature that is received at the inlet port 270 of the at least one cooling channel 210 flows through the at least one cooling channel 210 that is provided in the cooling circuit board 214, heat from the plurality of electronic components 212 that is positioned in the circuit board 213 is transferred to the liquid refrigerant. The transfer of heat from the plurality of electronic components 212 that is positioned in the circuit board 213 to the liquid refrigerant converts the refrigerant that is in the substantially liquid state to the refrigerant that is in the substantially gaseous state. The refrigerant that is in the substantially gaseous state is therein circulated to the outlet port 229 of the at least one cooling channel 210 at a higher temperature than that of the liquid refrigerant at the low pressure and the lower temperature that is received at the inlet port 270 of the at least one cooling channel 210.

In an exemplary embodiment, inner walls of the at least one cooling channel 210 provided in the cooling circuit board 214 may be manufactured from a material that can withstand pressurized corrosive liquid refrigerant at low temperature. In an exemplary embodiment, the inner walls of the at least one cooling channel 210 provided in the cooling circuit board 214 may be manufactured from but is not limited to a mild steel material, a pressure resistant glass material, a pressure resistant plastic material, a pressure resistant ceramic material, and a pressure resistant polymer material. In an alternate exemplary embodiment, the inner walls of the at least one cooling channel 210 provided in the cooling circuit board 214 may be manufactured from a high thermal conductivity material that facilitates efficient heat transfer from the plurality of electronic components 212 that are positioned in the circuit board 213 to the circuit board 213 that houses the plurality of electronic components 212 therein and subsequently to the refrigerant that flows through the at least one cooling channel 210 provided in the cooling circuit board 214. Moreover, the inner walls of the at least one cooling channel 210 provided in the cooling circuit board 214 may be coated with a leak resistant coating material to ensure containment of refrigerant within the at least one cooling channel 210 provided in the cooling circuit board 214 itself without being discharged to the external environment.

In an exemplary embodiment, a cooling fan 290 is mechanically coupled to the cooling circuit board 214. More specifically, the cooling fan 290 that is mechanically coupled to the cooling circuit board 214 receives rotational torque from an electric motor (not shown) that receives electric energy from an external power source such but not limited to an electric battery and a wall mounted electric socket. The rotation of the cooling fan 290 that is mechanically coupled to the cooling circuit board 214 facilitates delivering a stream of high speed cooling air to the condenser 230 to cool the refrigerant that is received in the condenser 230 from the outlet port 282 of the compressor 220. More specifically, the condenser 230 is positioned in an air flow path of the cooling fan 290 that is mechanically coupled to the cooling circuit board 214 and receives a stream of high speed cooling air that is discharged from the cooling fan 290 and impinges on an outer surface of the condenser 130. The stream of high speed cooling air that is discharged from the cooling fan 290 that is mechanically coupled to the cooling circuit board 214 and impinges on the outer surface of the condenser 130 cools the refrigerant that flows to the condenser 230 from the outlet port 282 of the compressor 220. Therefore, the cooling fan 290 facilitates discharging heat from the refrigerant that flows through the condenser 230. More specifically, the heat that was absorbed by the refrigerant that was channeled through the at least one cooling channel 210 provided in the cooling circuit board 214 from the circuit board 213 as well as the plurality of electronic components 212 that are positioned in the circuit board 213, and the heat that was absorbed by the refrigerant that was channeled through the compressor 220 due to compression of the refrigerant in the compressor 220 is therein discharged in the condenser 130 due to the stream of high speed cooling air that is discharged from the cooling fan 290 and impinges on the outer surface of the condenser 230. Therefore, at an outlet port 284 of the condenser 230, substantially gaseous refrigerant at high pressure and a lower temperature than the temperature of the refrigerant at the inlet port 285 of the condenser 130 is channeled to the next stage of the cooling system 100 for the circuit board 110 that houses the plurality of electronic components 212 therein. In an exemplary embodiment, the condenser 130 is in flow communication with the outlet port 282 of the compressor 220 and receives gaseous refrigerant at high pressure and at a high temperature therein from the compressor 220.

The refrigerant that flows through the at least one cooling channel 210 provided in the cooling circuit board 214 to cool the circuit board 213 that houses the plurality of electronic components 212 therein is of a specific heat absorption capacity that is greater in comparison with a specific heat absorption capacity of high speed cooling air that is of a specific heat absorption capacity that is lesser. Therefore, since the specific heat absorption capacity of the refrigerant that flows through the at least one cooling channel 210 provided in the cooling circuit board 214 is higher in comparison with the specific heat absorption capacity of high speed cooling air that is lower, a lower mass flow rate of refrigerant is required to be channeled through the at least one cooling channel 210 provided in the cooling circuit board 214. More specifically, the lower mass flow rate of refrigerant is required to be channeled through the at least one cooling channel 210 provided in the cooling circuit board 214 to decrease a first temperature of the circuit board 213 that houses the plurality of electronic components 212 therein to a second temperature in comparison with a higher mass flow rate of high speed cooling air that is required to be discharged from the cooling fan and allowed to impinge on the circuit board 213 that houses the plurality of electronic components 212 therein to decrease the first temperature of the circuit board 213 that houses the plurality of electronic components 212 therein to the second temperature. Therefore, in order to decrease the temperature of the circuit board 213 that houses the plurality of electronic components 212 therein from the first temperature to the second temperature, a lower mass flow rate of refrigerant is required to be channeled through the at least one cooling channel 210 provided in the cooling circuit board 214 to decrease the first temperature of the circuit board 213 that houses the plurality of electronic components 212 therein to the second temperature in comparison with a higher mass flow rate of high speed cooling air that is required to be discharged from the cooling fan and allowed to impinge on the circuit board 213 that houses the plurality of electronic components 212 therein. The high specific heat absorption capacity of the liquid refrigerant implies that a low mass flow rate of refrigerant that is channeled through the at least one cooling channel 210 is sufficient to absorb a substantially same amount of heat from the circuit board 213 as well as the plurality of electronic components 212 as that of a high mass flow rate of high speed cooling air that has a comparatively low specific heat absorption capacity to decrease the first temperature of the circuit board 213 that houses the plurality of electronic components 212 therein to the second temperature.

In an exemplary embodiment, a total amount of energy that is required for operating the compressor 220 to compress refrigerant flowing from the outlet port 229 of the at least one cooling channel 210 provided in the cooling circuit board 214 and delivering the compressed refrigerant to the inlet port 285 of the condenser 130, for channeling the refrigerant through the condenser 130, for channeling the refrigerant through the expansion device 140, and finally for channeling the refrigerant through the at least one cooling channel 210 provided in the cooling circuit board 214 is lesser in comparison with a total amount of energy that is required for operating the electric fan to discharge high speed cooling air in the circuit board 213 and the plurality of electronic components 212 that are positioned in the circuit board 213 because the low mass flow rate of refrigerant is required to be channeled through the at least one cooling channel 210 provided in the cooling circuit board 214 to decrease the first temperature of the circuit board 213 that houses the plurality of electronic components 212 therein to the second temperature in comparison with the high mass flow rate of high speed cooling air that is required to be discharged from the cooling fan and allowed to impinge on the circuit board 213 to decrease the first temperature of the circuit board 213 that houses the plurality of electronic components 212 therein to the second temperature. The lower mass flow rate of the refrigerant that is required to be channeled through the at least one cooling channel 210 provided in the cooling circuit board 214 to cool the circuit board 213 that houses the plurality of electronic components 212 therein from the first temperature to the second temperature requires a comparatively lower total amount of energy to be supplied to the compressor 120 for circulating the refrigerant through the cooling system 100 for the circuit board 110 that houses the plurality of electronic components 212 therein.

In an exemplary embodiment, the circuit board 213 comprises the plurality of electronic components 212 that are positioned in the circuit board 213. More specifically, the plurality of electronic components 212 that are positioned in the circuit board 213 becomes heated up due to the flow of electric current through the plurality of electronic components 212. Therefore, the plurality of electronic components 212 that are positioned in the circuit board 213 are required to be cooled by means of the cooling system 200 for the circuit board 213 that houses the plurality of electronic components 212 therein to ensure that the temperature of the plurality of electronic components 212 is maintained within acceptable operating temperature limits. In an exemplary embodiment, the plurality of cooling channels are provided in the lower surface of the circuit board 213 and adjoins the plurality of electronic components 212 such that the plurality of cooling channels and the plurality of electronic components 212 are separated physically by the circuit board 213.

In an exemplary embodiment, the first cooling channel 211 of the plurality of cooling channels that are provided in the lower surface of the circuit board 213 comprises the inlet port 270. More specifically, the inlet port 270 of the first cooling channel 211 of the plurality of cooling channels that are provided in the lower surface of the circuit board 213 receives refrigerant in the substantially liquid state. The refrigerant that is received in the substantially liquid state via the inlet port 270 of the first cooling channel 211 flows past the plurality of electronic components 212 that are positioned in the circuit board 213 and that requires to be cooled, wherein the plurality of electronic components 212 that are positioned in the circuit board 213 is separated from the first cooling channel 211 by the circuit board 213. On flowing past the plurality of electronic components 212 that are positioned in the circuit board 213 and cooling the plurality of electronic components 212 that are located proximate to the first cooling channel 211, the refrigerant is channeled through the second cooling channel 214 that is in flow communication with the first cooling channel 211 to facilitate cooling the plurality of electronic components 212 that are located proximate to the second cooling channel 214. In a similar manner, the third cooling channel 219 and the fourth cooling channel 215 are in flow communication with one another in series to ensure a smooth flow of the liquid refrigerant that is channeled through the inlet port 270 of the first cooling channel 211 to the fourth cooling channel 215 via the second cooling channel 214 and via the third cooling channel 219 that are each in flow communication with one another, and that are provided between the first cooling channel 211 and the fourth cooling channel 215 respectively. From the fourth cooling channel 215, the refrigerant is channeled through each of the subsequent plurality of cooling channels until it is channeled out of the last cooling channel that is provided in the cooling circuit board 214. In the exemplary embodiment, the last cooling channel is the sixteenth cooling channel 241. The first cooling channel 211, the second cooling channel 214, the third cooling channel 219, and the fourth cooling channel 215 each adjoin the plurality of electronic components 212 that are positioned in the circuit board 213 and are separated by the circuit board 213 and that is required to be cooled by liquid refrigerant that is channeled through the inlet port 270 of the first cooling channel 211. In an exemplary embodiment, the last cooling channel contains the outlet port 229 that receives the refrigerant that flows through the first cooling channel 211, the second cooling channel 214, the third cooling channel 219, and the fourth cooling channel 215 respectively. In an alternate exemplary embodiment, the first cooling channel 211 contains the outlet port 229 that receives the refrigerant that flows through the first cooling channel 211, the second cooling channel 214, the third cooling channel 219, the fourth cooling channel 215 and so on until the last cooling channel, and is circulated back to the first cooling channel 211 via a return flow path (not shown). As the liquid refrigerant that is in a substantially liquid state flows from the inlet port 270 of the first cooling channel 211 and circulates through the second cooling channel 214, the third cooling channel 219, the fourth cooling channel 215, and so on until the last cooling channel that is in flow communication with the first cooling channel 211, the liquid refrigerant changes its state to a gaseous state as a consequence of absorbing heat from the plurality of electronic components 212 that are positioned in the circuit board 213. Thereafter, the refrigerant in the substantially gaseous state is channeled through the outlet port 229 that is in flow communication with the last cooling channel to the next stage of the cooling system 200 for the circuit board 213 that houses the plurality of electronic components 212 therein. During the process of refrigerant flow through the first cooling channel 211, the second cooling channel 214, the third cooling channel 219, the fourth cooling channel 215, and so on until the last cooling channel of the circuit board 213, each of the plurality of electronic components 212 that are positioned in the circuit board 213 are cooled to a temperature that is within its acceptable operating temperature limit. Therefore, the flow of refrigerant that is channeled through the inlet port 270 of the first cooling channel 211, and channeled through the outlet port 229 of the last cooling channel facilitates decreasing the temperature of the circuit board 213 as well as the plurality of electronic components 212 that are positioned in the circuit board 213 within its acceptable operating temperature limits. In an exemplary embodiment, more than sixteen cooling channels or less than sixteen cooling channels may be deployed to cool the circuit board 213 that houses the plurality of electronic components 212 therein depending on a size of the circuit board 213 and an amount of heat that is generated by the plurality of electronic components 212 that are positioned in the circuit board 213.

In an exemplary embodiment, the circuit board 213 that includes at least one cooling channel 210 and the plurality of electronic components 212 may be a unitary circuit board. More specifically, the circuit board 213 may include the at least one cooling channel 210 that is provided in the circuit board 213 and extends between the inlet port 270 of the at least one cooling channel 210 and an outlet port 229 of the at least one cooling channel 210 as well as the plurality of electronic components 212 that are positioned in the circuit board 213 is a single integrated circuit board. Therefore, in this arrangement, both the at least one cooling channel 210 and the plurality of electronic components 212 may be integrally provided in the same circuit board 213 itself as a unitary assembly without having to assemble the at least one cooling channel 210 and the plurality of electronic components 212 on independent circuit boards and securing the independent circuit boards together by means of a fastener. In an alternate exemplary embodiment, the cooling circuit board 214 comprises at least one cooling channel 210 that is provided in the cooling circuit board 214 and extends between the inlet port 270 of the cooling circuit board 214 and the outlet port 229 of the cooling circuit board 214. The cooling circuit board 214 that comprises at least one cooling channel 210 that is provided in the cooling circuit board 214 is mechanically secured to the circuit board 213 by positioning an upper surface of the cooling circuit board 214 against a lower surface of the circuit board 213 that houses the plurality of electronic components 212 on the upper surface of the circuit board 213. Therein, the upper surface of the cooling circuit board 214 that includes at least one cooling channel 210 is secured to the lower surface of the circuit board 213 that houses the plurality of electronic components 212 on the upper surface of the circuit board 213 is secured thereto by means of a fastener. In an exemplary embodiment, the fastener that secures the upper surface of the cooling circuit board 214 that includes at least one cooling channel 210 to the lower surface of the circuit board 213 that houses the plurality of electronic components 212 on the upper surface of the circuit board 213 may be via a welded joint or a mechanical fastener. In an alternate exemplary embodiment, the fastener that secures the upper surface of the cooling circuit board 214 that comprises at least one cooling channel 210 to the lower surface of the circuit board 213 that houses the plurality of electronic components 212 on the upper surface of the circuit board 213 may be any kind of fastening means known in the art that facilitates securing the upper surface of the cooling circuit board 214 to the lower surface of the circuit board 213. In yet another alternate exemplary embodiment, the fastener may only be applied on the mating side interfaces of the cooling circuit board 214 that includes at least one cooling channel 210 and the circuit board 213 that houses the plurality of electronic components 212 therein to facilitate securing the cooling circuit board 214 to the circuit board 213.

In an exemplary embodiment, the at least one cooling channel 210 of the plurality of cooling channels may be positioned on a bottom surface of the cooling circuit board 214 to facilitate absorbing heat by the refrigerant flowing through the at least one cooling channel 210 of the plurality of cooling channels from the circuit board 213. More specifically, in an exemplary embodiment the at least one cooling channel 210 of the plurality of cooling channels may be mechanically coupled to the bottom surface of the cooling circuit board 214 and secured thereto by means of a fastener. Alternatively, in an exemplary embodiment, the at least one cooling channel 210 of the plurality of cooling channels may be integrally formed in the bottom surface of the cooling circuit board 214 during a manufacturing stage of the cooling circuit board 214 to constitute a unitary cooling circuit board 214/at least one cooling channel 210 assembly. In an alternate exemplary embodiment, the at least one cooling channel 210 of the plurality of cooling channels may be positioned within a substrate of the cooling circuit board 214 and may be located between an upper surface of the cooling circuit board 214 and the bottom surface of the cooling circuit board 214 to facilitate absorbing heat by the refrigerant flowing through the at least one cooling channel 210 of the plurality of cooling channels from the circuit board 213. More specifically, in an exemplary embodiment the at least one cooling channel 210 of the plurality of cooling channels may be mechanically coupled between the upper surface of the cooling circuit board 214 and the bottom surface of the cooling circuit board 214 and secured thereto by means of a fastener. Alternatively, in an exemplary embodiment, the at least one cooling channel 210 of the plurality of cooling channels may be integrally formed in the cooling circuit board 214 and located between the upper surface of the cooling circuit board 214 and the bottom surface of the cooling circuit board 214 during a manufacturing stage of the cooling circuit board 214 to constitute a unitary cooling circuit board 214/at least one cooling channel 210 assembly. In another alternate exemplary embodiment, the at least one cooling channel 210 of the plurality of cooling channels may be positioned on the upper surface of the cooling circuit board 214 to facilitate absorbing heat by the refrigerant flowing through the at least one cooling channel 210 of the plurality of cooling channels from the circuit board 213. More specifically, in an exemplary embodiment the at least one cooling channel 210 of the plurality of cooling channels may be mechanically coupled to the upper surface of the cooling circuit board 214 and secured thereto by means of a fastener.

Alternatively, in an exemplary embodiment, the at least one cooling channel 210 of the plurality of cooling channels may be integrally formed in the upper surface of the cooling circuit board 214 during a manufacturing stage of the cooling circuit board 214 to constitute a unitary cooling circuit board 214/at least one cooling channel 210 assembly. In a further alternate exemplary embodiment, the at least one cooling channel 210 of the plurality of cooling channels may be positioned on a lower surface of the circuit board 213 itself to facilitate absorbing heat by the refrigerant flowing through the at least one cooling channel 210 of the plurality of cooling channels from the circuit board 213. More specifically, in an exemplary embodiment the at least one cooling channel 210 of the plurality of cooling channels may be mechanically coupled to the bottom surface of the circuit board 213 and secured thereto by means of a fastener. Alternatively, in an exemplary embodiment, the at least one cooling channel 210 of the plurality of cooling channels may be integrally formed in the bottom surface of the circuit board 213 during a manufacturing stage of the circuit board 213 to constitute a unitary circuit board 213/at least one cooling channel 210 assembly. In yet another alternate exemplary embodiment, the at least one cooling channel 210 of the plurality of cooling channels may be positioned within a substrate of the circuit board 213 and may be located between an upper surface of the circuit board 213 and the lower surface of the circuit board 213 to facilitate absorbing heat by the refrigerant flowing through the at least one cooling channel 210 of the plurality of cooling channels from the circuit board 213. More specifically, in an exemplary embodiment the at least one cooling channel 210 of the plurality of cooling channels may be mechanically coupled between the upper surface of the circuit board 213 and the bottom surface of the circuit board 213 and secured thereto by means of a fastener. Alternatively, in an exemplary embodiment, the at least one cooling channel 210 of the plurality of cooling channels may be integrally formed in the circuit board 213 and located between the upper surface of the circuit board 213 and the bottom surface of the circuit board 213 during a manufacturing stage of the circuit board 213 to constitute a unitary circuit board 213/at least one cooling channel 210 assembly. The at least one cooling channel 210 of the plurality of cooling channels may be optimally positioned and integrally formed either with the cooling circuit board 214 or with the circuit board 213 to constitute a unitary assembly either with the cooling circuit board 214 or with the circuit board 213 respectively to facilitate absorbing a maximum amount of heat from the circuit board 213 as well as the plurality of electronic components 212 that are positioned in the circuit board 213.

In an exemplary embodiment, the at least one cooling channel 210 provided in the cooling circuit board 214 may be at least one micro-channel that receives a refrigerant therein. Therein, a diameter of the micro-channel that receives the refrigerant therein may be in the range of 0.01 millimeters to 0.2 millimeters to facilitate the flow of refrigerant through the at least one micro-channel. Alternatively, the diameter of the micro-channel that receives the refrigerant therein may be of the order of any diametrical range known in the art that facilitates the flow of refrigerant from the inlet port 270 of the micro-channel to the outlet port 229 of the micro-channel. In yet another alternate exemplary embodiment, the at least one cooling channel 210 provided in the cooling circuit board 214 may be at least one mini-channel that receives a refrigerant therein. Therein, a diameter of the mini-channel that receives the refrigerant therein may be in the range of 0.2 millimeters to 3 millimeters to facilitate the flow of refrigerant through the at least one mini-channel. Alternatively, the diameter of the mini-channel that receives the refrigerant therein may be of the order of any diametrical range known in the art that facilitates the flow of refrigerant from the inlet port 270 of the mini-channel to the outlet port 229 of the mini-channel.

In an exemplary embodiment, the plurality of electronic components 212 are positioned in the circuit board 213 and generates heat due to current that flows through the plurality of electronic component 212. The heat that is generated by the plurality of electronic components 212 that is positioned in the circuit board 213 is discharged to the circuit board 213 itself by conduction and consequently heats up the circuit board 213 that houses the plurality of electronic components 212 therein. Therefore, the refrigerant that flows through the at least one cooling channel 210 provided in the cooling circuit board 214 cools the plurality of electronic components 212 that are positioned in the circuit board 213. More specifically, as the refrigerant flows through the at least one cooling channel 210 provided in the cooling circuit board 214, the heat that is discharged from the plurality of electronic components 212 that are positioned in the circuit board 213 to the circuit board 213 is absorbed by the refrigerant flowing through the at least one cooling channel 210 by convection as refrigerant flows from the inlet port 270 of the at least one cooling channel 210 to the outlet port 229 of the at least one cooling channel 210. The absorption of heat by the refrigerant from the circuit board 213 facilitates cooling the heated circuit board 213 and consequently the heated plurality of electronic components 212 that are positioned in the heated circuit board 213. Therefore, once the refrigerant flows through the at least one cooling channel 210 that is provided in the cooling circuit board 214, the refrigerant cools the plurality of electronic components 212 that are positioned in the circuit board 213. More specifically, as the substantially liquid refrigerant that is at a high speed, low pressure, and low temperature that is received at the inlet port 270 of the at least one cooling channel 210 flows through the at least one cooling channel 210 that is provided in the cooling circuit board 214, heat from the plurality of electronic components 212 that are positioned in the circuit board 213 is transferred to the liquid refrigerant via the circuit board 213. The transfer of heat from the plurality of electronic components 212 that are positioned in the circuit board 213 to the liquid refrigerant flowing through the at least one cooling channel 210 converts the refrigerant that is in the substantially liquid state to the refrigerant that is in the substantially gaseous state. The refrigerant that is in the substantially gaseous state is therein circulated to the outlet port 229 of the at least one cooling channel 210 at a higher temperature than that of the liquid refrigerant at the low pressure and the lower temperature that is received at the inlet port 270 of the at least one cooling channel 210.

In an exemplary embodiment, an inner wall of the at least one cooling channel 210 provided in the cooling circuit board 214 may be manufactured from a material that can withstand pressurized corrosive liquid refrigerant at low temperature. More specifically, as the liquid refrigerant flows along the inner wall of the at least one cooling channel 210, the inner wall of the at least one cooling channel 210 is susceptible to contraction due to the low temperature pressurized liquid refrigerant, thereby causing deformations to occur on the inner wall of the at least one cooling channel 210. Therefore, the inner wall of the at least one cooling channel 210 is required to be manufactured from the material that can withstand pressurized liquid refrigerant at low temperature to ensure that the at least one cooling channel 210 does not contract and break down, thereby causing leakage of the pressurized liquid refrigerant from the at least one cooling channel 210 to the external environment. In an exemplary embodiment, the inner wall of the at least one cooling channel 210 provided in the cooling circuit board 214 may be manufactured from but is not limited to a mild steel material, a pressure resistant glass material, a pressure resistant plastic material, a pressure resistant polymer material, and a pressure resistant ceramic material. In an alternate exemplary embodiment, the inner wall and the outer wall of the at least one cooling channel 210 provided in the cooling circuit board 214 may be manufactured from a high thermal conductivity material that facilitates efficient heat transfer from the circuit board 213 to the refrigerant flowing through the at least one cooling channel 210. Moreover, the inner wall of the at least one cooling channel 210 provided in the cooling circuit board 214 may be coated with a leak resistant coating material to ensure containment of liquid/gaseous refrigerant within the at least one cooling channel 210 provided in the cooling circuit board 214 itself without being discharged to the external environment.

In an exemplary embodiment, a cooling fan 290 is mechanically coupled to the cooling circuit board 214. More specifically, the cooling fan 290 that is mechanically coupled to the cooling circuit board 214 receives rotational torque from an electric motor (not shown) that receives electric energy from an external power source such as but not limited to an electric battery and a wall mounted electric socket. The rotation of the cooling fan 290 causes a rotation of a plurality of fan blades 293 that are coupled to the cooling fan 290 that is mechanically coupled to the cooling circuit board 214 and facilitates delivering a stream of cooling air to the condenser 230 to cool the refrigerant that is received in the condenser 230 from the outlet port 282 of the compressor 220. More specifically, the condenser 230 is positioned in an air flow path of the cooling fan 290 that is mechanically coupled to the cooling circuit board 214 and receives a stream of cooling air that is discharged from the cooling fan 290 and impinges on the outer surface of the condenser 130. The stream of cooling air that is discharged from the cooling fan 290 that is mechanically coupled to the cooling circuit board 214 and impinges on the outer surface of the condenser 130 facilitates withdrawal of heat away from the outer surface of the condenser 230 to the external environment due to the process of convection, thereby cooling the refrigerant that is channeled to the inlet port 285 of the condenser 230 from the outlet port 282 of the compressor 220 and that flows through the condenser 230. Therefore, the cooling fan 290 facilitates discharging heat from the refrigerant that flows through the condenser 230. More specifically, the heat that was absorbed by the refrigerant that was channeled through the inlet port 270 at least one cooling channel 210 provided in the cooling circuit board 214 from the circuit board 213 as well as the plurality of electronic components 212 that are positioned in the circuit board 213, and the heat that was absorbed by the refrigerant that was channeled through the compressor 220 due to compression of the refrigerant in the compressor 220 is therein discharged in the condenser 230 due to the stream of cooling air that is discharged from the cooling fan 290 and impinges on the outer surface of the condenser 230 thereby decreasing the temperature of the refrigerant that flows through the condenser 230 substantially. Therefore, at the outlet port 284 of the condenser 230, substantially gaseous refrigerant at high pressure and a lower temperature than the temperature of the refrigerant that was channeled to the inlet port 285 of the condenser 230 is channeled to the next stage of the cooling system 200 for the circuit board 213 that houses the plurality of electronic components 212 therein. In an alternate exemplary embodiment, a plurality of fins may be secured to the outer surface of the condenser 230 and receives heat from the outer surface of the condenser 230. The heat that is received by the plurality of fins from the outer surface of the condenser 230 facilitates decreasing a temperature in the condenser 230, thereby causing heat from the refrigerant to be discharged to the external environment and substantially cooling the refrigerant that is present in the condenser 230. In an exemplary embodiment, the condenser 230 is in flow communication with the outlet ort 282 of the compressor 220 and receives gaseous refrigerant at high pressure and at a high temperature within the condenser 230.

The refrigerant that flows through the at least one cooling channel 210 provided in the cooling circuit board 214 to cool the circuit board 213 that houses the plurality of electronic components 212 therein is of a specific heat absorption capacity that is greater in comparison with respect to a specific heat absorption capacity of high speed cooling air that is of a specific heat absorption capacity that is lesser. Therefore, since the specific heat absorption capacity of the refrigerant that flows through the at least one cooling channel 210 provided in the cooling circuit board 214 is higher in comparison with the specific heat absorption capacity of high speed cooling air that is lower, a lower mass flow rate of refrigerant is required to be channeled through the at least one cooling channel 210 provided in the cooling circuit board 214. More specifically, the lower mass flow rate of refrigerant is required to be channeled through the at least one cooling channel 210 provided in the cooling circuit board 214 to decrease the first temperature of the circuit board 213 that houses the plurality of electronic components 212 therein to the second temperature in comparison with a higher mass flow rate of high speed cooling air that is required to be discharged from the cooling fan and allowed to impinge on the circuit board 213 that houses the plurality of electronic components 212 therein to decrease the first temperature of the circuit board 213 that houses the plurality of electronic components 212 therein to the second temperature. Therefore, in order to decrease the temperature of the circuit board 213 that houses the plurality of electronic components 212 therein from the first temperature to the second temperature, a lower mass flow rate of refrigerant is required to be channeled through the at least one cooling channel 210 provided in the cooling circuit board 214 to decrease the first temperature of the circuit board 213 that houses the plurality of electronic components 212 therein to the second temperature in comparison with a higher mass flow rate of high speed cooling air that is required to be discharged from the cooling fan and allowed to impinge on the circuit board 213 that houses the plurality of electronic components 212 therein. The high specific heat absorption capacity of the liquid refrigerant implies that a low mass flow rate of refrigerant that is channeled through the at least one cooling channel 210 is sufficient to absorb a substantially same amount of heat from the circuit board 213 that houses the plurality of electronic components 212 as that of a high mass flow rate of high speed cooling air that has a comparatively low specific heat absorption capacity to decrease the first temperature of the circuit board 213 that houses the plurality of electronic components 212 therein to the second temperature.

In an exemplary embodiment, an outlet valve (not shown) is in flow communication between the outlet port 229 of the at least one cooling channel 210 provided in the cooling circuit board 214 and the inlet port 281 of the compressor 220. More specifically, the outlet valve 240 is in flow communication between the outlet port 229 of the at least one cooling channel 210 and the inlet port 281 of the compressor 220 and is electronically connected to the electronic control unit 250 via a control flow path. Therefore, the electronic control unit 250 controls the flow of refrigerant from the outlet port 229 of the at least one cooling channel 210 to the inlet port 281 of the compressor 220 via the outlet valve that is in flow communication between the outlet port 229 of the at least one cooling channel 210 provided in the cooling circuit board 214 and the inlet port 281 of the compressor 220.

In addition, the circuit board 213 that houses the plurality of electronic components 212 therein further comprises the plurality of electronic components 212 that are positioned in the circuit board 213 on a surface of the circuit board 213 that faces away from the at least one cooling channel 210 that is provided on an opposing face of the circuit board 213. In an exemplary embodiment, the at least one cooling channel 210 is secured to or integrally formed with the face of the circuit board 213 that opposes the face of the circuit board 213 that houses the plurality of electronic components 212 therein. In an alternate exemplary embodiment, the at least one cooling channel 210 is provided within or integrally formed with the circuit board 213 and is located between the two opposing end faces of the circuit board. More specifically, the refrigerant that flows through the at least one cooling channel 210 flows past the plurality of electronic components 212 that are positioned in the circuit board 213. Therefore, the refrigerant that flows past the plurality of electronic components 212 that are positioned in the circuit board 213 cools the circuit board 213 as well as the plurality of electronic components 212 that are positioned in the circuit board 213. The cooling of the circuit board 213 as well as the plurality of electronic components 212 that are positioned in the circuit board 213 facilitates decreasing the temperature of the circuit board 213 as well as the plurality of electronic components 212 that are positioned in the circuit board 213 and maintained within their respective acceptable operating temperature limits, thereby enhancing a longevity of the plurality of electronic components 212 that are positioned in the circuit board 213. After refrigerant is channeled through the at least one cooling channel 210, the circuit board 213 and the plurality of electronic components 212 that are positioned in the circuit board 213 may be cooled to different operating temperatures, but still be within the acceptable operating temperature limit of the circuit board 213 and within the acceptable operating temperature limit of the plurality of electronic components 212 respectively.

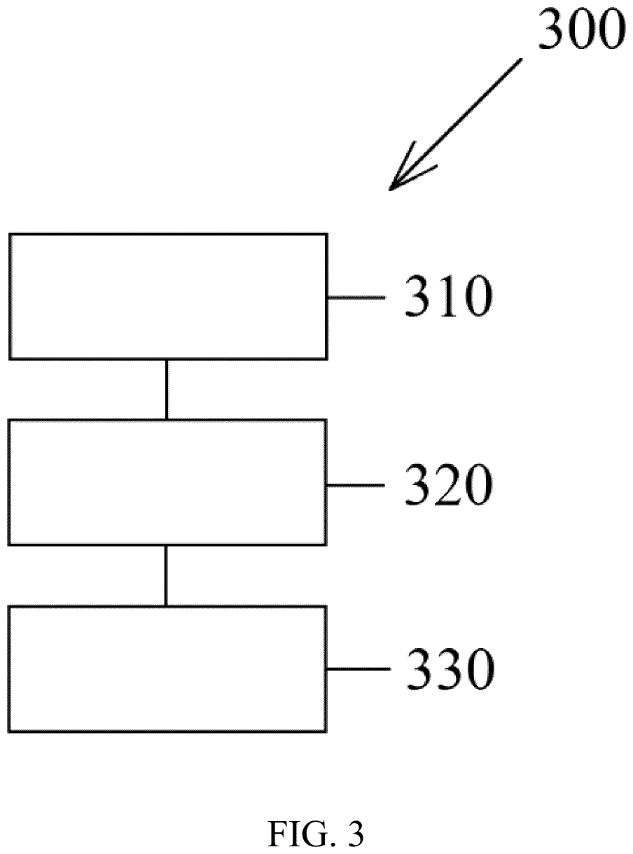

FIG. 3 is a flowchart representing a method 300 of production of a circuit board 213 in one embodiment of the invention. The method 300 comprises providing 310 at least one cooling channel 210 in the circuit board 213 that houses the plurality of electronic components 212 therein. The at least one cooling channel 210 comprises the inlet port 270 and the outlet port 229. The method further comprises channeling 320 refrigerant in a substantially liquid state at a low temperature through the inlet port 270 of the at least one cooling channel 210 such that the refrigerant that is channeled in the substantially liquid state at the low temperature through the inlet port 270 of the at least one cooling channel 210 flows through the at least one cooling channel 210 and past the plurality of electronic components 212 to cool the circuit board 213 that houses the plurality of electronic components 212 therein. The method 300 comprises delivering 330 refrigerant that flows through the at least one cooling channel 210 to cool the circuit board 213 that houses the plurality of electronic components 212 therein through the outlet port 229 of the at least one cooling channel 210 in a substantially gaseous state at a high temperature due to absorption of heat by the refrigerant from the circuit board 213 that houses the plurality of electronic components 212 therein.

A working of the cooling system 200 for the circuit board 213 that houses the plurality of electronic components 212 therein is described as an example. In an exemplary embodiment, the refrigerant in the substantially liquid state is received within the at least one cooling channel 210 via the inlet port 270 that is defined in the at least one cooling channel 210. Once the liquid refrigerant is channeled within the at least one cooling channel 210 via the inlet port 270, the liquid refrigerant is allowed to flow through the at least one cooling channel 210 provided in the circuit board 213 that houses the plurality of electronic components 212 therein to facilitate cooling the circuit board 213 and the plurality of electronic components 212 that are positioned in the circuit board 213. More specifically, once the liquid refrigerant flows through the inlet port 270 of the at least one cooling channel 210, the liquid refrigerant is channeled through the first cooling channel 211, through the second cooling channel 214 that is in flow communication with the first cooling channel 211, through the third cooling channel 219 that is in flow communication with the second cooling channel 214, through the fourth cooling channel 215 that is in flow communication with the third cooling channel 219 and so on until the refrigerant is channeled through the last cooling channel that is in flow communication with the fourth cooling channel 215. The flow of liquid refrigerant through the first cooling channel 211, through the second cooling channel 214, through the third cooling channel 219, through the fourth cooling channel 215 and so on and finally through the last cooling channel facilitates cooling the circuit board 213 that houses the plurality of electronic components 212 therein. More specifically, as the liquid refrigerant flows through the first cooling channel 211, through the second cooling channel 214, through the third cooling channel 219, through the fourth cooling channel 215 and so on and finally through the last cooling channel respectively, the liquid refrigerant absorbs heat from the circuit board 213 that becomes heated up due to the transfer of heat from the plurality of electronic components 212 that are positioned in the circuit board 213 to the circuit board 213. More specifically, the plurality of electronic components 212 that are positioned in the circuit board 213 becomes heated up due to the flow of electric current through the plurality of electronic components 212 which in turn is transferred to the circuit board 213 by the process of conduction. The absorption of heat by the liquid refrigerant from the circuit board 213 changes the phase of the refrigerant from the liquid phase to the gaseous phase as refrigerant flows through the first cooling channel 211, through the second cooling channel 214, through the third cooling channel 219, through the fourth cooling channel 215 and so on until the sixteenth cooling channel 241 or the last cooling channel respectively. Therefore, when the liquid refrigerant enters the inlet port 270 of the first cooling channel 211, the liquid refrigerant is at low temperature and at low pressure. However, as the liquid refrigerant changes its phase to the gaseous phase during the process of heat absorption from the circuit board 213 as refrigerant flows through the first cooling channel 211, through the second cooling channel 214, through the third cooling channel 219, through the fourth cooling channel 215 and so on until the sixteenth cooling channel 241 or the last cooling channel respectively, the gaseous refrigerant that exits from the outlet port 229 of the last cooling channel is at high temperature and at low pressure. As heat flows from the circuit board 213 to the refrigerant that flows through the inlet port 270 of the at least one cooling channel 210, through the first cooling channel 211, through the second cooling channel 214, through the third cooling channel 219, through the fourth cooling channel 215 and so on until the sixteenth cooling channel 241 or the last cooling channel and through the outlet port 229 of the last cooling channel, the circuit board 213 is thereby cooled from the higher temperature to the lower temperature respectively.

The refrigerant at the outlet port 229 of the at least one cooling channel 210 provided in the circuit board 213 which is in the gaseous state at high temperature and at low pressure is channeled to the inlet port 281 of the compressor 220. Once the gaseous refrigerant is received in the compressor 220, the gaseous refrigerant is compressed by the compressor 220 from a pressure that is equal to the pressure of the refrigerant at the outlet port 229 of the at least one cooling channel 210 to a higher pressure that is required for the refrigerant to be circulated through the cooling system 200 for the circuit board 213 that houses the plurality of electronic components 212 therein. Therefore, as the gaseous refrigerant at high temperature and at low pressure flows through the compressor 220 via its inlet port 281, the compressor 220 increases the pressure of the refrigerant from the low pressure to a high pressure with a corresponding large increase in temperature of the refrigerant. Therefore, at the outlet port 282 of the compressor 220, the gaseous refrigerant is at a higher temperature than the gaseous refrigerant that is channeled to the inlet port 281 of the compressor 220 from the outlet port 229 of the at least one cooling channel 210 provided in the circuit board, and at a higher pressure than the gaseous refrigerant that is channeled to the inlet port 281 of the compressor 220 from the outlet port 229 of the at least one cooling channel 213 provided in the circuit board 213.

The refrigerant at the outlet port 282 of the compressor 220 which is in the gaseous state at high temperature and at high pressure is channeled to the inlet port 285 of the condenser 230. Once the gaseous refrigerant is received within the condenser 230 via its inlet port 285, heat that is present within the gaseous refrigerant that was absorbed by the refrigerant that was channeled through the at least one cooling channel 210 provided in the circuit board 213 from the circuit board 213 as well as the plurality of electronic components 212 that are positioned in the circuit board 213, and the heat that was absorbed by the refrigerant in the compressor 220 while the gaseous refrigerant was being compressed in the compressor 220 is dissipated in the condenser 230. More specifically, the cooling fan 290 that is mechanically coupled to the cooling circuit board 214 receives rotational torque from the electric motor that receives electric energy from an external power source such but not limited to an electric battery and a wall mounted electric socket. Therein, the cooling fan 290 that is mechanically coupled to the cooling circuit board 214 rotates, thereby channeling cooling air to the outer surface of the condenser 230. The cooling air from the cooling fan 290 that impinges on the outer surface of the condenser 230 channels heat away from the gaseous refrigerant that flows through a plurality of coiled pipes 248 in the condenser 230. More specifically, the plurality of coiled pipes 248 are in flow communication with the inlet port 285 of the condenser 230 at its one end and in flow communication with the outlet port 284 of the condenser 230 at its opposite second end and channels gaseous refrigerant through the condenser 230 to discharge heat from the gaseous refrigerant within the condenser 230. The coiled nature of the plurality of coiled pipes 248 facilitate increasing a length of travel of the gaseous refrigerant through a longitudinal length of the condenser 230 to facilitate discharging heat from the gaseous refrigerant within the condenser 230 effectively. Due to heat from the gaseous refrigerant that is channeled away by the cooling air that impinges on the outer surface of the condenser 230 that is discharged by the cooling fan 290, the temperature of the refrigerant that flows through the coiled pipes 248 of the condenser 230 from the inlet port 285 of the condenser 230 to the outlet port 284 of the condenser 230 is decreased from the temperature of the refrigerant at the inlet port 285 of the condenser 230 to a lower temperature at the outlet port 284 of the condenser 230 that is required for the refrigerant to be circulated through the cooling system 200 for the circuit board 213 that houses the plurality of electronic components 212 therein. While the temperature of the refrigerant decreases from the temperature at the outlet port 282 of the compressor 220 to the lower temperature as the refrigerant flows through the coiled pipes 248 of the condenser 230, the pressure of the refrigerant as refrigerant flows through a length of the condenser 230 remains steady or decreases to a slightly lower pressure from the high pressure gaseous refrigerant that is channeled from the outlet port 282 of the compressor 220 to the inlet port 285 of the condenser 230. Therefore, at the outlet port 284 of the condenser 230, the gaseous refrigerant is at a relatively lower temperature than the gaseous refrigerant that is channeled to the inlet port 285 of the condenser 230 from the outlet port 282 of the compressor 220, and at a substantially same pressure or slightly lower pressure as the gaseous refrigerant that is channeled to the inlet port 285 of the condenser 230 from the outlet port 282 of the compressor 220.

The refrigerant at the outlet port 284 of the condenser 230 which is in the gaseous state at low temperature and at high pressure is channeled to the inlet port 283 of the expansion device 240. The expansion device 240 is in flow communication with the outlet port 284 of the condenser 230 at its inlet port 283 and receives refrigerant that flows from the condenser 230 through the outlet port 284 of the condenser 230. Once the refrigerant is received at the inlet port 283 of the expansion device 240 in a substantially gaseous state, the expansion device 240 facilitates throttling the gaseous refrigerant thereby decreasing the pressure of the refrigerant that exits from the outlet port 284 of the condenser 230 to a lower pressure that exits from the outlet port 247 of the expansion device 240. Due to the decrease in the pressure of the refrigerant due to the throttling effect of the expansion device 240, the temperature of the refrigerant is decreased from the low temperature at the inlet port 283 of the expansion device 240 to a relatively much lower temperature that exits from the outlet port 247 of the expansion device 240. The expansion device 240 is in flow communication with the inlet port 270 of the at least one cooling channel 210 provided in the circuit board 213 at its outlet port 247. The expansion device 240 controls a flow of refrigerant that flows through the outlet port 284 of the condenser 230 to the inlet port 270 of the at least one cooling channel 210 provided in the circuit board 213, wherein the expansion device 240 is electronically controlled by means of the electronic control unit 250 that is in electronic communication with the expansion device 240 via the control flow path 271. More specifically, the electronic control unit 250 controls the opening percentage of the expansion device 240 to facilitate regulating the required mass flow rate of the refrigerant that is to flow from the outlet port 284 of the condenser 230 to the inlet port 270 of the at least one cooling channel 210 provided in the circuit board 213 for the refrigerant to be circulated through the cooling system 200 for the circuit board 213 that houses the plurality of electronic components 212 therein.

As the pressure and the temperature of the refrigerant decreases from high pressure and low temperature at the outlet port 284 of the condenser 230 to low pressure and much lower temperature that is required for the refrigerant to be circulated through the cooling system 200 for the circuit board 213 that houses the plurality of electronic components 212 therein, the refrigerant changes its phase to the substantially liquid phase due to the decrease in the temperature of the refrigerant below a phase transition temperature of the refrigerant that flows through the outlet port 247 of the expansion device 240 to the inlet port 270 of the at least one cooling channel 210. Moreover, the throttling of the refrigerant that flows through the outlet port 284 of the condenser 230 to the inlet port 270 of the at least one cooling channel 210 via the expansion device 240 that is controlled by the electronic control unit 250 via the control flow path 271 permits only the required mass flow rate of refrigerant to be channeled at high speed through the inlet port 270 of the at least one cooling channel 210. Therefore, at the outlet port 247 of the expansion device 240, substantially liquid refrigerant is at a lower pressure than the refrigerant that is channeled to the inlet port 283 of the expansion device 240 from the outlet port 284 of the condenser 230 and is at a lower temperature than the refrigerant that is channeled to the inlet port 283 of the expansion device 240 from the outlet port 284 of the condenser 230. In an exemplary embodiment, the inlet port 270 of the at least one cooling channel 210 provided in the circuit board 213 is in flow communication with the outlet port 247 of the expansion device 240 and receives high speed liquid refrigerant at low pressure and at low temperature therein. After the refrigerant in the substantially liquid state at low pressure and at low temperature is channeled to the inlet port 270 of the at least one cooling channel 210, the cycle is repeated once more with the flow of liquid refrigerant through the at least one cooling channel 210 provided in the circuit board 213 to cool the circuit board 213 and the plurality of electronic components 212 that are positioned in the circuit board 213.

The advantages of the cooling system 200 for the circuit board 213 that houses the plurality of electronic components 212 therein are now outlined below for the understanding of a reader. Since a low mass flow rate of refrigerant is required to be channeled through the at least one cooling channel 210 provided in the circuit board 213 to decrease the first temperature of the circuit board 213 that houses the plurality of electronic components therein to the second temperature in comparison with the high mass flow rate of high speed cooling air that is required to be discharged from the cooling fan and allowed to impinge on the circuit board 213 to decrease the first temperature of the circuit board 213 to the second temperature, the total amount of energy that is required to be expended for operating the compressor 220 to compress refrigerant flowing from the outlet port 229 of the at least one cooling channel 210 provided in the circuit board 213 and delivering the compressed refrigerant from the outlet port 282 of the compressor 220 to the inlet port 285 of the condenser 230 for channeling the refrigerant through the condenser 230, for channeling the refrigerant through the expansion device 240, and finally for channeling the refrigerant through the at least one cooling channel 210 provided in the circuit board 213 is much lower in comparison with the total amount of energy that is required to be expended for operating the cooling fan 290 for discharging high speed cooling air from the cooling fan 290 on the circuit board 213 that houses the plurality of electronic components 212 therein. Therefore, since the low mass flow rate of refrigerant is required to be channeled through the at least one cooling channel 210 provided in the circuit board to cool the circuit board 213 and the plurality of electronic components 212 that are positioned in the circuit board 213 by decreasing the first temperature of the circuit board 213 to the second temperature in comparison with the high mass flow rate of high speed cooling air that is required to be discharged from the cooling fan 290 on the circuit board 213 that houses the plurality of electronic components 212 therein to the second temperature, the total amount of energy that is required to be supplied to the compressor 220 for circulating the refrigerant through the cooling system 200 for the circuit board 213 that houses the plurality of electronic components 212 therein is much lesser than the total amount of energy that is required for discharging high speed cooling air from the cooling fan 290 on the circuit board 213 that houses the plurality of electronic components 212 therein.

In addition, the material cost savings associated with utilizing the liquid refrigerant for cooling the circuit board 213 that does not require to be replaced over an entire lifespan of the circuit board 213 is much higher than utilizing a cooling fan that is currently being deployed for cooling the circuit board 213 that requires to be replaced several times over the entire lifespan of the circuit board 213. In addition, a maintenance cost associated with maintaining the proposed cooling system 200 for the circuit board 213 utilizing the liquid refrigerant that requires minimal service and mechanical maintenance is much lower than the maintenance cost associated with maintaining the current cooling system 200 for the circuit board 213 utilizing the cooling fan that discharges high speed cooling air to the circuit board 213 that requires periodic maintenance and service. Therefore, the overall benefits associated with deploying the proposed liquid refrigerant that is to be circulated through the cooling system 200 of the circuit board 213 that houses the plurality of electronic components 212 therein to cool the circuit board 213 is much better than the overall benefits associated with deploying the cooling fan that discharges high speed cooling air on the circuit board 213 that is currently being circulated through the cooling system 200 of the circuit board 213 that houses the plurality of electronic components 212 therein to cool the circuit board 213.

Exemplary embodiments of a cooling system 200 for a circuit board 213 for cooling the circuit board 213 is described above in detail. The systems are not limited to the specific embodiments described herein, but rather, components of each system may be utilized separately and independently from other components described herein. In addition, the terms ‘printed circuit board’, ‘electronic circuit board’, ‘cooling circuit board’, and ‘circuit board’ may be used interchangeably herein in this manuscript. Therefore, each of these components may be used in place of one another in this manuscript.

While the invention has been described in terms of various specific embodiments, those skilled in the art will recognize that the invention can be practiced with modifications within the spirit and scope of the claims. cm What is claimed is:

1. A cooling system for a circuit board that houses at least one electronic component therein, said cooling system comprising:
at least one cooling channel provided to said circuit board and receives a refrigerant therein, wherein the refrigerant that is received in the at least one cooling channel flows through the at least one cooling channel to cool said circuit board that houses at least one electronic component therein;
a compressor in flow communication with an outlet of the at least one cooling channel provided to said circuit board, said compressor receives refrigerant that flows through the outlet of the at least one cooling channel, said compressor compresses the refrigerant that is received in said compressor;
a condenser in flow communication with an outlet of said compressor, said condenser receives refrigerant that flows through the outlet of said compressor, said condenser discharges heat from the refrigerant that is received in said condenser; and
an expansion device in flow communication with an outlet of said condenser at its inlet and receives refrigerant that flows through the outlet of said condenser, said expansion device in flow communication with an inlet of the at least one cooling channel provided to said circuit board at its outlet, wherein said expansion device controls a flow of refrigerant that flows through the outlet of said condenser to the inlet of the at least one cooling channel provided to said circuit board.

2. A cooling system for a circuit board in accordance with claim 1, wherein said circuit board that includes the at least one cooling channel and said at least one electronic component may be a unitary circuit board.

3. A cooling system for a circuit board in accordance with claim 1, further comprising a cooling circuit board and the at least one cooling channel provided to said cooling circuit board is secured to said circuit board by positioning said cooling circuit board against said circuit board that houses at least one electronic component therein and secured to said circuit board by means of a fastener.

4. A cooling system for a circuit board in accordance with claim 1, wherein said at least one cooling channel provided to said circuit board may be one of at least one micro-channel and at least one mini-channel that receives the refrigerant therein.

5. A cooling system for a circuit board in accordance with claim 1, further comprising at least one electronic component positioned in said circuit board, the refrigerant that flows through the at least one cooling channel provided to said circuit board cools the at least one electronic component positioned in said circuit board.

6. A cooling system for a circuit board in accordance with claim 1, wherein inner walls of the at least one cooling channel provided to said circuit board may be of a material that can withstand pressurized corrosive liquid refrigerant at low temperature, and wherein inner walls of the at least one cooling channel provided to said circuit board may be of a leak resistant material to ensure containment of substantially gaseous refrigerant within the at least one cooling channel provided to said circuit board.

7. A cooling system for a circuit board in accordance with claim 1, further comprising a cooling fan mechanically coupled to said circuit board and receives rotational torque from an electric motor, said cooling fan supplies a stream of cooling air to said condenser to cool refrigerant that is received in said condenser from the outlet of said compressor.

8. A cooling system for a circuit board in accordance with claim 1, wherein the refrigerant that flows through the at least one cooling channel provided to said circuit board to cool said circuit board that houses at least one electronic component therein is of a specific heat absorption capacity that is greater in comparison with a specific heat absorption capacity of high speed cooling air, thereby allowing for a low mass flow rate of refrigerant to be channeled through the at least one cooling channel provided to said circuit board to decrease a first temperature of said circuit board that houses said at least one electronic component therein to a second temperature in comparison with a high mass flow rate of high speed cooling air to be discharged from a cooling fan and allowed to impinge on the circuit board to decrease the first temperature of said circuit board that houses said at least one electronic component therein to the second temperature.

9. A cooling system for a circuit board in accordance with claim 1, wherein a total amount of energy required to operate said compressor for compressing the refrigerant, for channeling the refrigerant through said condenser, for channeling the refrigerant through said expansion device, and for channeling the refrigerant through the at least one cooling channel provided to said circuit board is lesser in comparison with total amount of energy required to operate a cooling fan to discharge high speed cooling air on the circuit board because a low mass flow rate of refrigerant is required to be channeled through the at least one cooling channel provided to said circuit board to decrease a first temperature of said circuit board that houses at least one electronic component therein to a second temperature in comparison with a high mass flow rate of high speed cooling air that is required to be discharged from said cooling fan and allowed to impinge on the circuit board to decrease the first temperature of said circuit board to the second temperature.

10. A cooling system for a circuit board in accordance with claim 1, further comprising an outlet valve in flow communication between the outlet of the at least one cooling channel and an inlet of said compressor and controls a flow of refrigerant from the outlet of the at least one cooling channel to the inlet of said compressor.

11. A cooling system for a circuit board in accordance with claim 1, wherein the at least one cooling channel is integrally formed in said circuit board such that the at least one cooling channel constitutes a unitary assembly with said circuit board.

12. A circuit board, said circuit board comprising:
at least one cooling channel provided to said circuit board, the at least one cooling channel comprises an inlet and an outlet, the inlet of the at least one cooling channel receives low temperature refrigerant, wherein the low temperature refrigerant that is received through the inlet of the at least one cooling channel flows through the at least one cooling channel to cool said circuit board by absorbing heat from said circuit board, and wherein high temperature refrigerant is delivered through the outlet of the at least one cooling channel.

13. A circuit board in accordance with claim 12, wherein said circuit board houses at least one electronic component therein, and wherein said circuit board that comprises at least one cooling channel and that houses at least one electronic component therein may be a unitary circuit board.

14. A circuit board in accordance with claim 12, further comprising a cooling circuit board and the at least one cooling channel provided to said cooling circuit board is secured to said circuit board by positioning said cooling circuit board against said circuit board and secured to said circuit board by means of a fastener.

15. A circuit board in accordance with claim 12, wherein said at least one cooling channel provided to said circuit board may be one of at least one micro-channel and at least one mini-channel that receives the refrigerant therein.

16. A circuit board in accordance with claim 12, further comprising at least one electronic component positioned in said circuit board, the refrigerant that flows through the at least one cooling channel provided to said circuit board cools the at least one electronic component positioned in said circuit board.

17. A circuit board in accordance with claim 12, wherein inner walls of the at least one cooling channel provided to said circuit board may be of a material that can withstand pressurized corrosive liquid refrigerant at low temperature, and wherein inner walls of the at least one cooling channel provided to said circuit board may be of a leak resistant material to ensure containment of substantially gaseous refrigerant within the at least one cooling channel provided to said circuit board.

18. A circuit board in accordance with claim 12, further comprising a cooling fan mechanically coupled to said circuit board and receives rotational torque from an electric motor, said cooling fan supplies a stream of cooling air to said condenser to cool refrigerant that is received in said condenser from the at least one cooling channel provided to said circuit board.

19. A circuit board in accordance with claim 12, wherein the refrigerant that flows through the at least one cooling channel provided to said circuit board to cool said circuit board that houses at least one electronic component therein is of a specific heat absorption capacity that is greater in comparison with a specific heat absorption capacity of high speed cooling air, thereby allowing for a low mass flow rate of refrigerant to be channeled through the at least one cooling channel provided to said circuit board to decrease a first temperature of said circuit board that houses at least one electronic component therein to a second temperature in comparison with a high mass flow rate of high speed cooling air to be discharged from a cooling fan and allowed to impinge on the circuit board to decrease the first temperature of said circuit board that houses at least one electronic component therein to the second temperature.

20. A circuit board in accordance with claim 12, further comprising an outlet valve in flow communication between the outlet of the at least one cooling channel and an inlet of a compressor and controls a flow of refrigerant from the outlet of the at least one cooling channel to the inlet of said compressor.

21. A circuit board in accordance with claim 12, wherein the at least one cooling channel is integrally formed in said circuit board such that the at least one cooling channel constitutes a unitary assembly with said circuit board.

22. A method of production of a circuit board, the method comprising:
providing at least one cooling channel to the circuit board that houses at least one electronic component therein, the at least one cooling channel comprising an inlet and an outlet;
channeling refrigerant in a substantially liquid state at a low temperature through the inlet of the at least one cooling channel such that the refrigerant that is channeled in the substantially liquid state at the low temperature through the inlet of the at least one cooling channel flows through the at least one cooling channel to cool the circuit board that houses at least one electronic component therein; and
delivering refrigerant that flows through the at least one cooling channel to cool the circuit board that houses at least one electronic component therein through the outlet of the at least one cooling channel in a substantially gaseous state at a high temperature due to absorption of heat by the refrigerant from the circuit board that houses at least one electronic component therein.
